(19) United States
(12) Patent Application Publication
(10) Pub. No.: US 2024/0078663 A1
(43) Pub. Date: Mar. 7, 2024

(54) METHOD FOR PROCESSING SUBSTRATE

(71) Applicant: PSK INC., Hwaseong-si (KR)

(72) Inventors: KWANG SUNG YOO, Hwaseong-si (KR); GEON JONG KIM, Hwaseong-si (KR)

(21) Appl. No.: 18/462,386

(22) Filed: Sep. 6, 2023

(30) Foreign Application Priority Data
Sep. 7, 2022 (KR) 10-2022-0113708

(51) Int. Cl. G06T 7/00; G06T 7/11; G06T 7/174; H01J 37/32

(52) U.S. Cl. CPC G06T 7/001; G06T 7/11; G06T 7/174; H01J 37/32348; H01J 37/3288; H01J 37/32899; H01J 2237/221; H01J 2237/24592; H01J 2237/3341

(57) ABSTRACT

The inventive concept provides a substrate treating method. The substrate treating method includes treating an edge region of a substrate using a plasma; and acquiring an image to be determined by imaging a substrate on which a treatment has been completed in the treating the edge region, comparing the image to be determined with an image stored in a database, and determining whether a substrate treated in the treating the edge region is defective or not, and wherein the image stored in the database is a defective image of a substrate which has been determined as defective, which is previously stored in the database in the acquiring the image to be determined.

### CROSS-REFERENCE TO RELATED APPLICATIONS

A claim for priority under 35 U.S.C. § 119 is made to Korean Patent Application No. 10-2022-0113708 filed on Sep. 7, 2022, in the Korean Intellectual Property Office, the entire contents of which are hereby incorporated by reference.

### BACKGROUND

Embodiments of the inventive concept described herein relate to a substrate treating method, more specifically, a substrate treating method using a plasma.

A plasma refers to an ionized gas state composed of ions, radicals, and electrons, and is produced by very high temperatures, strong electric fields, or high-frequency electromagnetic fields. A semiconductor element manufacturing process includes an ashing process or an etching process of removing a film on a substrate using the plasma. The ashing process or the etching process is performed by colliding or reacting with the film on the substrate by ion and radical particles contained in the plasma.

The ashing process or the etching process is performed in a process chamber. In order to determine whether a substrate on which a treatment has been completed treated in the process chamber is defective, an operator must manually check the substrate. When the operator checks each substrate one by one, a time required for the checking process increases, and it is different to secure an objectivity of a determination, because a criteria for determining whether the substrate is defective is different for each operator.

In addition, components made of a dielectric are installed in the process chamber. These components are damaged in a process of treating the substrate by the plasma formed in the process chamber. In addition, foreign substances (Byproduct) generated in a process of treating the substrate get attached to and deposited on these components. If the components are damaged or a large amount of foreign substances get attached to the components, the operator must perform a maintenance operation on abnormal components. However, even if a large amount of foreign substances get attached to the components, there is no way to check them in advance. If the substrate is treated using the plasma while a large amount of foreign substances are attached to the components, the film formed on the substrate cannot be removed according to a required recipe.

### SUMMARY

Embodiments of the inventive concept provide a substrate treating method for efficiently determining whether a substrate having completed a treatment using a plasma is defective or not.

Embodiments of the inventive concept provide a substrate treating method for efficiently determining a replacement time of components included in a substrate treating apparatus.

The technical objectives of the inventive concept are not limited to the above-mentioned ones, and the other unmentioned technical objects will become apparent to those skilled in the art from the following description.

The inventive concept provides a substrate treating method. The substrate treating method includes treating an edge region of a substrate using a plasma; and acquiring an image to be determined by imaging a substrate on which a treatment has been completed in the treating the edge region, comparing the image to be determined with an image stored in a database, and determining whether a substrate treated in the treating the edge region is defective or not, and wherein the image stored in the database is a defective image of a substrate which has been determined as defective, which is previously stored in the database in the acquiring the image to be determined.

In an embodiment, in the acquiring the image to be determined, if the image to be determined matches any one among defective images, it is determined that a treatment is defective in the treating the edge region.

In an embodiment, if the image to be determined matches any one among the defective images, the image to be determined is stored in the database.

In an embodiment, if the image to be determined matches any one among the defective images, a maintenance operation with respect to a component of a process chamber performing the treating the edge region is performed.

In an embodiment, the process chamber includes: a support unit configured to support the substrate; a dielectric plate positioned above the support unit to face a central region of a substrate supported on the support unit; and a plasma source generating a plasma at an edge region of the substrate supported on the support unit, and wherein the component includes a dielectric plate.

In an embodiment, when the image to be determined matches any one among the defective images, when the image to be determined is stored in the database, a data of a current state of the dielectric plate matching the image to be determined is stored in the database, and if it is determined that a subsequent image to be determined matches at least any one among the defective images, a replacement time of the dielectric plate is determined based on the data which is matched with the subsequent image to be determined.

In an embodiment, a replacement period of the dielectric plate is calculated based on a determined replacement time, and a set number of the substrate treated in the treating the edge region is calculated according to the replacement period, and if a substrate of a calculated set number is treated at the treating the edge region, the dielectric plate is replaced.

In an embodiment, at the acquiring the image to be determined, whether a boundary displayed on the image to be determined and a boundary displayed on the defective image is determined, and the boundary is between the edge region of the substrate which is treated by the plasma and a central region of the substrate.

In an embodiment, the substrate having the edge region treated is transferred to a load lock chamber in the treating the edge region, and the acquiring the image to be determined is performed in the load lock chamber.

In an embodiment, in the load lock chamber the image to be determined is acquired by imaging the edge region of the chamber by rotating the substrate.

The inventive concept provides a substrate treating method. The substrate treating method includes treating an edge region of a substrate using a plasma at a process chamber including a plasma source generating the plasma at the edge region of the substrate supported on a support unit and a dielectric plate positioned above the support unit to face the support unit; acquiring an image to be determined by imaging a substrate on which a treatment is completed, and determining whether the image to be determined and an image stored in a database match; and performing a maintenance operation on the dielectric plate if the image to be determined matches at least any one among images stored in the database.

In an embodiment, the image stored in the database is a defective image of a substrate which has been determined as needing the maintenance operation, which is previously stored in the database.

In an embodiment, when the image to be determined matches any one among defective images and the image to be determined is stored in the database, a data of a current state of the dielectric plate matching the image to be determined is stored in the database, and if it is determined that a subsequent image to be determined matches at least any one among the defective images, a replacement time of the dielectric plate is determined based on the data which is matched with the subsequent image to be determined.

In an embodiment, a replacement period of the dielectric plate is calculated based on a determined replacement period.

In an embodiment, a set number of a substrate treated using the plasma is calculated according to the replacement period, and if a substrate of a calculated set number is treated, the dielectric plate is replaced.

In an embodiment, whether the image to be determined matches the defective image is determined based on whether a boundary displaying the image to be determined and a boundary displayed on the defective image match, and the boundary is between the edge region of the substrate which is treated by the plasma the central region of the substrate.

In an embodiment, whether a boundary displayed on the image to be determined and a boundary displayed on the defective image is determined, and the boundary is between the edge region of the substrate which is treated by the plasma and a central region of the substrate.

According to an embodiment of the inventive concept, whether a substrate on which a treatment has been completed using a plasma is defective may be determined.

According to an embodiment of the inventive concept, a replacement time of components included in a substrate treating apparatus may be determined.

According to an embodiment of the inventive concept, an optimal replacement time of components included in a substrate treating apparatus may be set.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a cross-sectional view schematically illustrating a substrate treating apparatus according to an embodiment.

FIG. 2 is a cross-sectional view schematically illustrating a load lock chamber according to an embodiment of FIG. 1.

FIG. 3 is a cross-sectional view schematically illustrating a process chamber according to an embodiment of FIG. 1.

FIG. 4 is a flowchart of a substrate treating method according to an embodiment.

FIG. 5 is a cross-sectional view schematically illustrating the substrate treating apparatus performing a treating step according to an embodiment.

FIG. 6 illustrates a substrate on which the treating step is completed according to an embodiment viewed from above.

FIG. 7 schematically illustrates a defective image according to an embodiment.

FIG. 8 to FIG. 10 schematically illustrate embodiments in which an image to be determined is compared with defective images.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

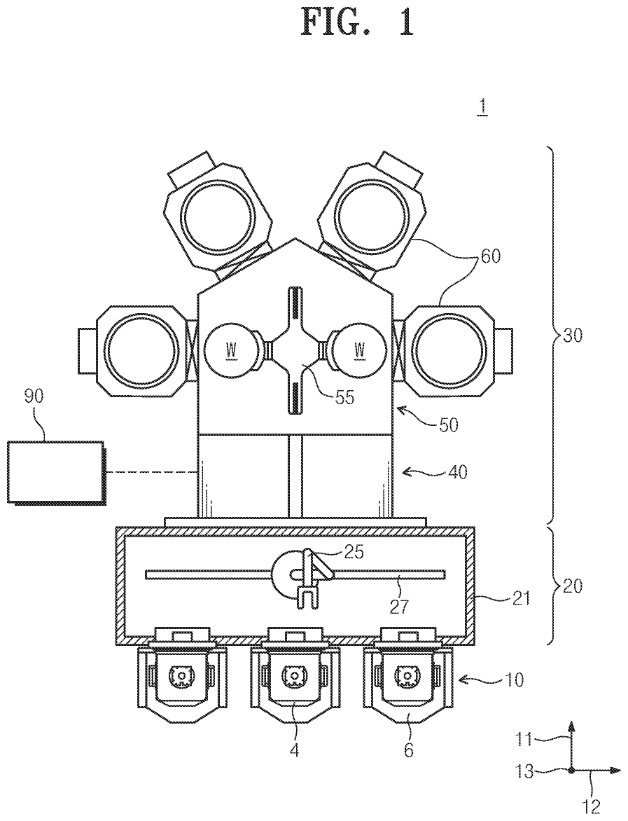

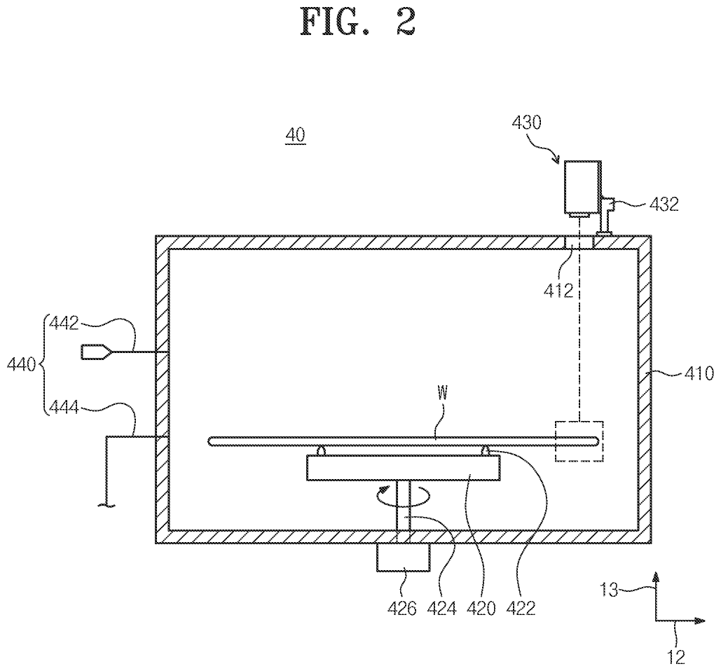

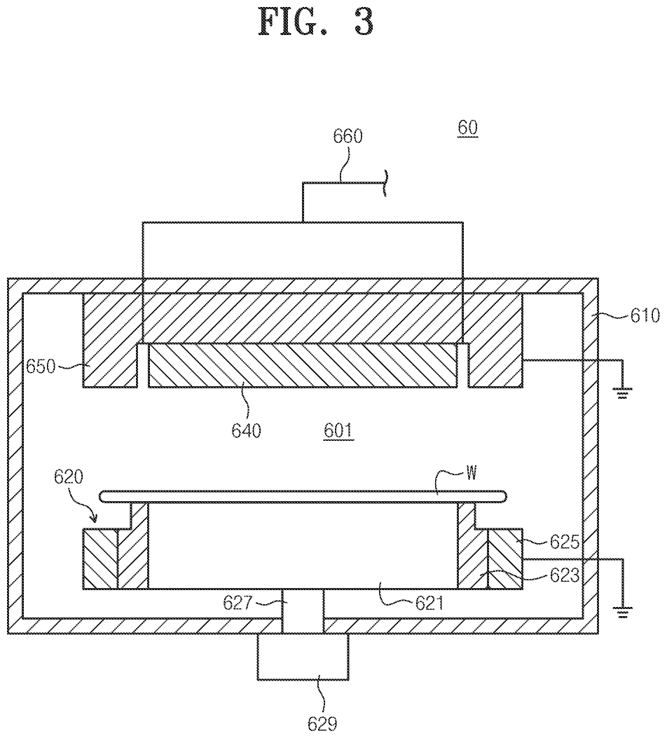

FIG. 1 is a cross-sectional view schematically illustrating a substrate treating apparatus according to an embodiment. FIG. 2 is a cross-sectional view schematically illustrating a load lock chamber according to an embodiment of FIG. 1. FIG. 3 is a cross-sectional view schematically illustrating a process chamber according to an embodiment of FIG. 1.

Hereinafter, a substrate treating apparatus according to an embodiment of the inventive concept will be described with reference to FIG. 1 to FIG. 3.

The substrate treating apparatus 1 has a front end module 20 (Equipment Front End Module) and a treating module 30. The front end module 20 and the treating module 30 are disposed in a direction.

Hereinafter, a direction in which the front end module 20 and the treating module are disposed is defined as a first direction 11. In addition, when viewed from above, a direction perpendicular to the first direction 11 is defined as a second direction 12, and a direction perpendicular to a plane including both the first direction 11 and the second direction 12 is defined as a third direction 13. For example, the third direction 13 may be a direction perpendicular to the ground.

The front end module 20 has a load port 10 and a transfer frame 21. The load port has a plurality of support portions 6. Each of the support portions 6 may be arranged in a direction along the second direction 12. A container 4 may be mounted on each support portion 6. The container 4 according to an embodiment may include a cassette, a FOUP, or the like. The container 4 may contain a substrate W scheduled for a predetermined treatment in the process chamber 60 to be described later and a substrate W on which a predetermined treatment has been completed in the process chamber 60.

The transfer frame 21 is disposed between the load port 10 and the treating module 30. The transfer frame 21 has an inner space. The inner space of the transfer frame 21 may be maintained in an atmospheric pressure atmosphere. A first transfer robot 25 and a transfer rail 27 are disposed within the transfer frame 21. The first transfer robot 25 forwardly and backwardly moves on the transfer rail 27 having a horizontal lengthwise direction with the second direction 12 and transfers the substrate W between the container 4 and the treating module 30.

The treating module 30 according to an embodiment may include a load lock chamber 40, a transfer chamber 50, and a process chamber 60.

The load lock chamber 40 is disposed adjacent to the front end module 20. For example, the load lock chamber 40 may be disposed between the transfer frame 21 and the transfer chamber 50. A plurality of load lock chambers 40 may be provided. For example, the load lock chamber 40 may be provided in an arrangement of 2×2 in the second direction 12 and the third direction 13. However, the inventive concept is not limited thereto, and the number and arrangement of the load lock chambers 40 may be variously changed. Since the structure of the plurality of load lock chambers 40 are mostly the same or similar, any one load lock chamber 40 among the plurality of load lock chambers 40 will be described below for convenience of explanation.

The load lock chamber 40 may include a housing 410, a support 420, a vision unit 430, and an atmosphere conversion unit 440.

The housing 410 may have a substantially rectangular parallelepiped shape. The housing 410 has an inner space. The inner space of the housing 410 functions as a space at which a substrate W scheduled for a predetermined treatment stands-by before being transferred to the process chamber 60 or a substrate W on which the predetermined treatment is completed stands-by before being transferred to the container 4. A door (not shown) communicating with the inner space of the transfer frame 21 is formed on a sidewall of the housing 410. In addition, the door (not shown) communicating with the inner space of the transfer chamber 50 to be described later is formed on the other sidewall facing the sidewall of the housing 410. In addition, a port 412 made of a transparent material capable of transmitting a light is formed on a top wall of the housing 410.

The support 420 is positioned in the inner space of the housing 410. The support 420 may have a disk shape. The support 420 has a diameter smaller than that of the substrate W. Accordingly, an edge region of the substrate W may be positioned outside the support 420. A plurality of support pins 422 may be disposed on a top surface of the support 420. The plurality of support pins 422 are in contact with a bottom surface of the substrate W to support the substrate W.

The rotary shaft 424 has a rod shape. An end of the rotary shaft 424 is coupled to a bottom end of the support 420, and the other end of the rotary shaft 424 is connected to a rotary driver 426. The rotary driver 426 rotates the rotary shaft 424. When the rotary shaft 424 is rotated by the rotary driver 426, the support 420 and the substrate W are rotated together. The rotary driver 426 may be any one of known motors.

The vision unit 430 images a surface on which a pattern is formed on the substrate W. In addition, the edge region of the substrate W is imaged. More specifically, the vision unit 430 acquires an image by imaging the edge region of the substrate W which has been treated in the process chamber 60 described later. As will be described later, the image acquired by the vision unit 430 may be defined as an image to be determined.

The vision unit 430 is coupled to a bracket 432 installed on a top wall of the housing 410. Accordingly, the vision unit 430 may be coupled to the housing 410 via the bracket 432. The aforementioned port 412 is positioned on an imaging path of the vision unit 430. The vision unit 430 may be a known camera module of which a focus is automatically adjusted. While the support 420 is rotated, the vision unit 430 may image an entire edge region of the substrate W.

The atmosphere conversion unit 440 may change an atmosphere of the inner space of the housing 410. For example, the atmosphere conversion unit 440 may change the atmosphere of the inner space of the housing 410 between an atmospheric pressure and a vacuum pressure. The atmosphere conversion unit 440 may include a gas supply line 442 and a gas discharge line 444.

The gas supply line 442 supplies a gas to the inner space of the housing 410. For example, the gas supply line 442 may supply an inert gas. In addition, the gas discharge line 444 exhausts the atmosphere of the inner space of the housing 410. A pump (not shown) is installed in the gas discharge line 444. The pump (not shown) may exhaust the atmosphere of the inner space of the housing 410 by applying a negative pressure to the inside of the gas discharge line 444.

The transfer chamber 50 transfers the substrate W between the load lock chamber 40 and the process chamber 60. The transfer chamber 50 is disposed adjacent to the load lock chamber 40. The transfer chamber 50 may have a polygonal body. The load lock chamber 40 and a plurality of process chambers 60 may be disposed along a circumference of a body of the transfer chamber 50.

An inside of the transfer chamber 50 may be generally maintained in a high-pressure atmosphere. A second transfer robot 55 is disposed within the transfer chamber 50. The second transfer robot 55 transfers the substrate W between the load lock chamber 40 and the process chambers 60. In addition, the second transfer robot 55 may transfer the substrate W between the process chambers 60. More specifically, the second transfer robot 55 transfers an untreated substrate W standing by in the load lock chamber 40 to the process chamber 60, or a substrate W on which a predetermined treatment has been completed in the process chamber 60 to the load lock chamber 40.

In the process chamber 60, a treating process with respect to the substrate W may be performed. A plurality of process chambers 60 may be provided. A treating process performed in the process chambers 60 may be different from each other. Hereinafter, the process chamber 60 which treats the substrate W using a plasma among the process chambers 60 will be described as an example.

More specifically, a process chamber 60 which performs a Bevel Etch process which removes a film on the edge region of the substrate W among the process chambers 60 is described as an example. The film may include various types of films such as a polysilicon film, an oxide film, and a silicon nitride film. Selectively, the film may be a natural oxide film or a chemically produced oxide film. The film may be a foreign substance (Byproduct) generated in a process of treating the substrate. Selectively, the film may be a foreign substance attached to and/or remaining on the top and bottom surfaces of the substrate.

However, the inventive concept is not limited to this, and the process chamber 60 described below may be applied equally or similarly to a chamber that performs various processes for treating the substrate W. In addition, the process chamber 60 described below can be applied equally or similarly to various chambers which treat the substrate W using a plasma.

The process chamber 60 may include a housing 610, a support unit 620, a dielectric plate 640, and a top electrode unit 650.

The housing 610 has a treating space 601 in which the substrate W is treated. The housing 610 may have a substantially hexahedral shape. In addition, the housing 610 may be grounded. An opening (not shown) through which the substrate W is taken in and out may be formed on the sidewall of the housing 610.

The support unit 620 is positioned in the treating space 601 and supports the substrate W. The support unit 620 may include a support plate 621, an insulating ring 623, and a bottom edge electrode 625.

The substrate W is mounted on a top surface of the support plate 621. The support plate 621 has a substantially circular shape when viewed from above. In addition, the support plate 621 may have a diameter smaller than that of the substrate W.

A support shaft 627 is coupled to a bottom end of the support plate 621. The support shaft 627 has a vertical lengthwise direction. An end of the support shaft 627 is coupled to the bottom end of the support plate 621, and the other end thereof is connected to the shaft driver 629. The shaft driver 629 moves the support shaft 627 in the vertical direction, and accordingly, the support plate 621 and the substrate W move in the vertical direction.

A power supply unit 630 applies a power to the support plate 621. The power supply unit 630 may include a power source 632, a matching unit 634, and a power line 636. The power source 632 may apply a bias voltage or a high frequency voltage to the support plate 621. The power source 632 is electrically connected to the support plate 621 via the power line 636. The matching unit 634 may be installed on the power line 636 to match an impedance.

The insulating ring 623 has a ring shape. The insulating ring 623 is disposed between the support plate 621 and the bottom edge electrode 625 to be described later. More specifically, the insulating ring 623 is disposed to surround an outer circumferential surface of the support plate 621. According to an embodiment, the insulating ring 623 may be made of an insulating material. In addition, the insulating ring 623 may have a stepped top surface. For example, the insulating ring 623 may be stepped so that a height of the top surface of the inner region thereof is higher than a height of a top surface of the outer region. In addition, the top surface of the inner region of the insulating ring 623 may be positioned at the same height as the top surface of the support plate 621.

The bottom edge electrode 625 has a ring shape. The bottom edge electrode 625 is disposed to surround an outer circumferential surface of the insulating ring 623. When viewed from above, the bottom edge electrode 625 is disposed in the edge region of the substrate W supported by the support plate 621. That is, the bottom edge electrode 625 is positioned below the edge region of the substrate W supported by the support plate 621. In addition, the top surface of the bottom edge electrode 625 may be positioned at the same height as the top surface of the outer region of the insulating ring 623. The bottom edge electrode 625 may be grounded.

The dielectric plate 640 may be a disk-shaped dielectric substance. The dielectric plate 640 is disposed to face the support plate 621 above the support plate 621. Accordingly, the bottom surface of the dielectric plate 640 and the top surface of the substrate W supported by the support plate 621 face each other. The dielectric plate 640 is coupled to a bottom end of the top electrode unit 650.

The top electrode unit 650 is disposed above the support unit 620. The top electrode unit 650 is disposed to surround the dielectric plate 640. More specifically, the top electrode unit 650 may surround a side end and a top end of the dielectric plate 640.

The top electrode unit 650 may include a top portion and a bottom portion. The top portion of the top electrode unit 650 may have a disk shape. In addition, the bottom portion of the top electrode unit 650 may be formed to downwardly protrude from the top portion and may have a ring shape. The bottom portion of the top electrode unit 650 may be disposed to surround an outer circumferential surface of the dielectric plate 640. The bottom portion of the top electrode unit 650 is disposed to face the bottom edge electrode 625 above the bottom edge electrode 625. Accordingly, the bottom portion of the top electrode unit 650 is positioned above the edge region of the substrate W supported by the support plate 621. The bottom portion of the top electrode unit 650 may function as an electrode facing the bottom edge electrode 625.

In addition, an inner circumferential surface of a bottom portion of the top electrode unit 650 may be disposed to be spaced apart from an outer circumferential surface of the dielectric plate 640. A gas line 660 is connected to a separation space. The separation space overlaps the edge region of the substrate W supported by the support plate 621 when viewed from above. The gas line 660 supplies a gas to the treating space 601. The gas supplied to the treating space may be a gas excited by a plasma.

The controller 90 may control the substrate treating apparatus 1. The controller 90 may control components included in the substrate treating apparatus 1 to perform the substrate treating method described below. The controller may comprise a process controller consisting of a microprocessor (computer) that executes a control of the substrate treating apparatus, a user interface such as a keyboard via which an operator inputs commands to manage the substrate treating apparatus, and a display showing the operation situation of the substrate treating apparatus, a database storing a treating recipe or images, etc, and a control program for operating a treatment in the substrate treating apparatus 1 via a control of a process controller, or a program for performing a control of each component according to each data or treating conditions, or a matching program for determining whether an stored image matches an acquired image may be provided. In addition, the user interface and database may be connected to the process controller.

Hereinafter, a substrate treating method according to an embodiment of the inventive concept will be described. Since the substrate treating method described below is performed in the substrate treating apparatus 1 described with reference to FIG. 1 to FIG. 3, the reference numerals cited in FIG. 1 to FIG. 3 are cited in the same manner below.

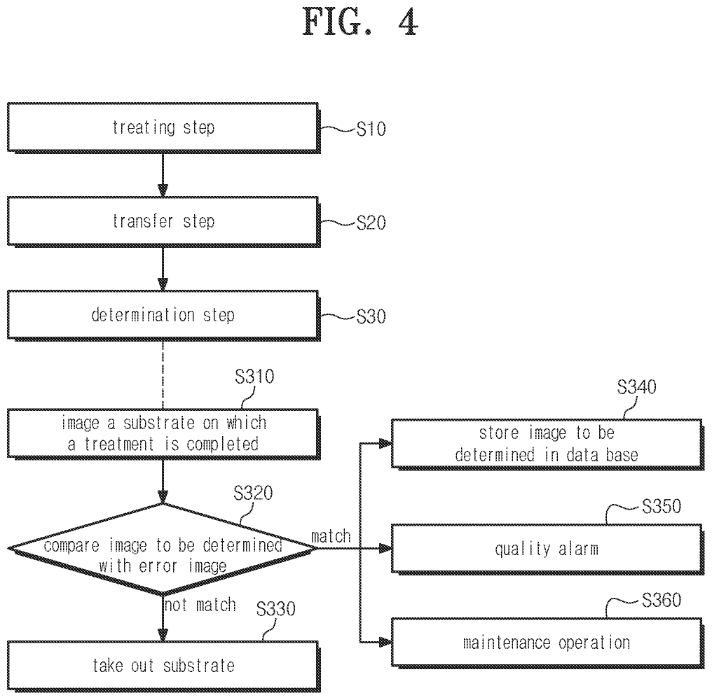

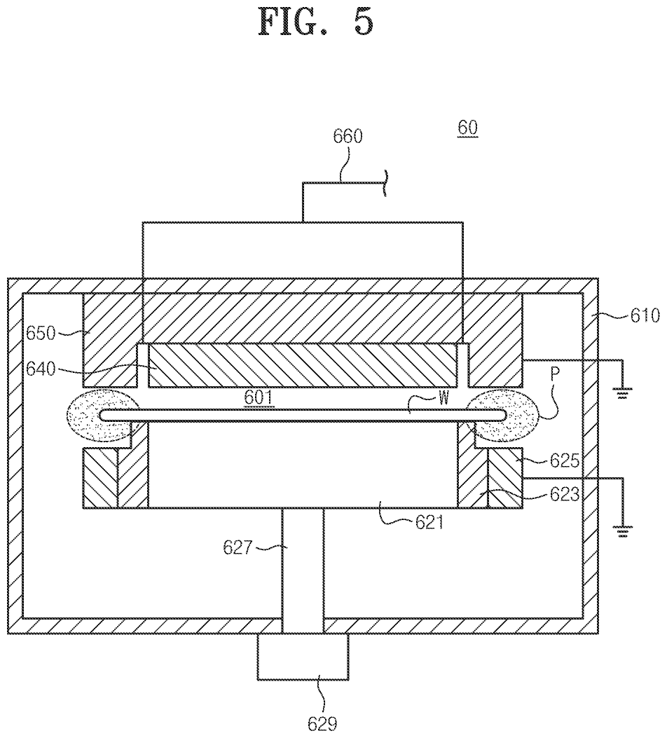

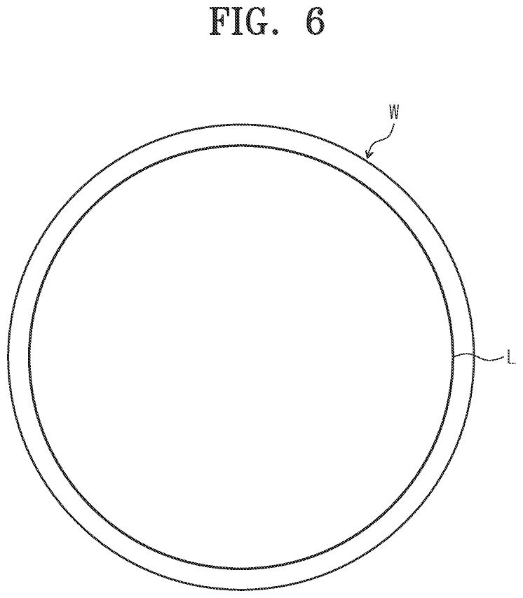

FIG. 4 is a flowchart of a substrate treating method according to an embodiment. FIG. 5 and FIG. 6 schematically illustrate the substrate treating apparatus performing a treating step according to an embodiment and a substrate on which the treating step is performed, respectively.

Referring to FIG. 4, the substrate treating method according to an embodiment may include a treating step S10, a transfer step S20, and a determination step S30. The treating step S10, the transfer step S20, and the determination step S30 may be performed in the order of time series.

Referring to FIG. 4 and FIG. 5, the treating step S10 is performed in the process chamber 60. In the treating step S10, a film formed in the edge region of the substrate W may be removed using the plasma.

In the treating step S10, a gas is supplied to the edge region of the substrate W through the gas line 660. The support plate 621, the grounded bottom edge electrode 625 and the grounded top electrode unit 650 to which a high frequency power is applied or a bias power is applied interacts electrically with each other to form an electronic field in the edge region of the substrate W. The gas supplied to the edge region of the substrate W by the electric field formed in the edge region of the substrate W may be excited to the plasma P in the edge region of the substrate W. The plasma P formed in the edge region of the substrate W may remove the film formed in the edge region of the substrate W. Accordingly, the support plate 621, the bottom edge electrode 625 and the top electrode unit 650 according to an embodiment function as a plasma source.

Referring to FIG. 4 and FIG. 6, in the treating step S10, the plasma is generated in the edge region of the substrate W to remove the film formed in the edge region of the substrate W, so a step may occur between the edge region of the substrate W and the central region of the substrate W. Accordingly, a boundary line L may be displayed between the central region and the edge region of the substrate W on which the treating step S10 is completed.

If the substrate W which has been treated in the treating step S10 is good quality, the boundary line L may be smoothly displayed along the edge of the substrate W. That is, when the film formed in the edge region of the substrate W is well removed in the treating step S10, the boundary line L can be generally displayed in the form of a curvature circle or a circle. On the other hand, if a large amount of foreign substances (Byproduct) are attached to the dielectric plate 640, the dielectric plate 640 is damaged by the plasma, or some components contained in the process chamber 60 are damaged, so the film formed in the edge region of the substrate W cannot be well removed. In this case, the boundary line L displayed on the treated substrate W is not displayed in a curvature circle or a circle shape, but is displayed in a curved manner.

Also, referring to FIG. 4, the transfer step S20 transfers the treated substrate W from the process chamber 60 to the load lock chamber 40. More specifically, the second transfer robot 55 takes out the treated substrate W from the process chamber 60 and transfers it to the load lock chamber 40. The substrate W transferred to the load lock chamber 40 may be supported by a plurality of support pins 422.

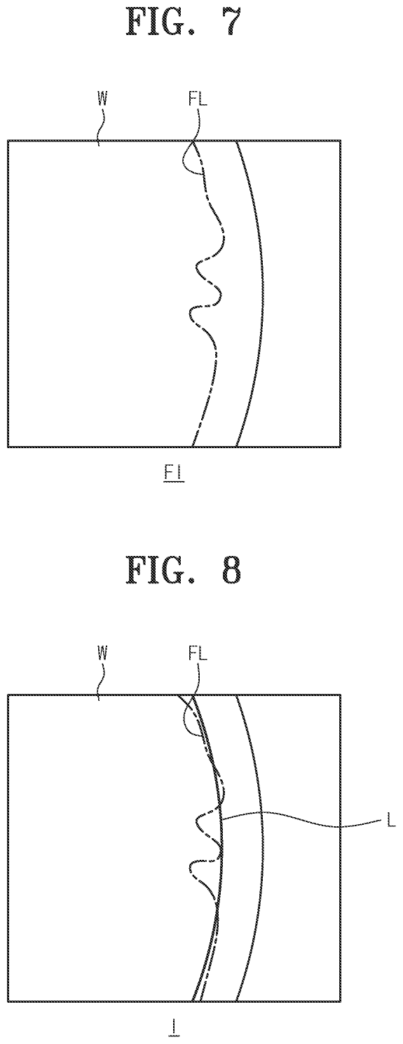

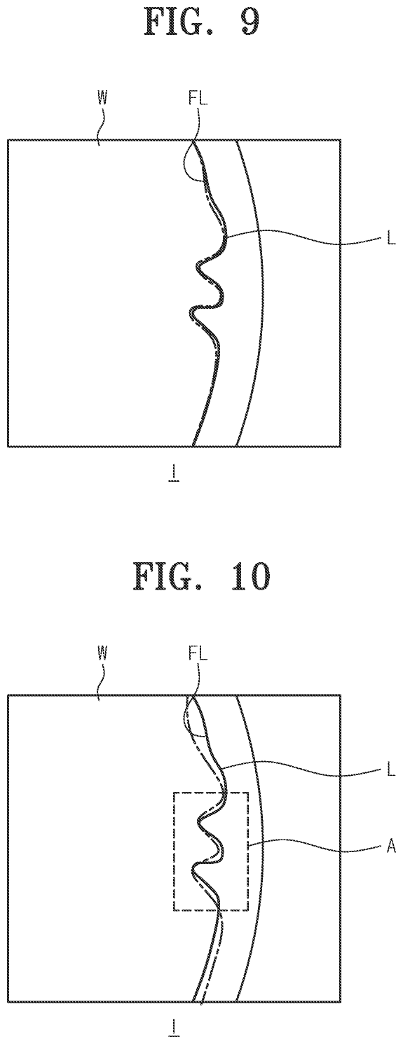

FIG. 7 schematically illustrates a defective image according to an embodiment. FIG. 8 illustrates an embodiment in which a treated substrate is determined to be good quality. FIGS. 9 and 10 are views illustrating embodiments illustrating a case in which a treated substrate is determined to be defective.

Hereinafter, a determination step according to an embodiment of the inventive concept will be described with reference to FIG. 4 and FIG. 7 to FIG. 10.

In the determination step S30, it is determined whether the treated substrate W is defective. In addition, in the determination step S30, a replacement time of the dielectric plate 640 is determined.

The determination step S30 is performed in the load lock chamber 40. The vision unit 430 images the substrate W supported by the support pin 422. More specifically, the vision unit 430 images the substrate W that has been treated in the treating step S10 S310. The vision unit 430 acquires an image to be determined by imaging the edge region of the substrate W.

According to an embodiment, the image to be determined acquired by the vision unit 430 may be a partial region of the entire edge region of the substrate W. For each substrate W that has been treated, there may be a plurality of images to be determined acquired by the vision unit 430. For example, the vision unit 430 may image a rotating substrate W. Accordingly, the vision unit 430 may repeatedly image a partial region of the entire edge region of the rotating substrate W to acquire the plurality of images to be determined for the entire edge region of the substrate W.

The vision unit 430 transmits an acquired image to be determined to the controller 90. The controller 90 compares the image to be determined with a plurality of defective images previously stored in the database S320. More specifically, the controller 90 compares a boundary line displayed on the image to be determined with a boundary line displayed on the plurality of defective images previously stored in the database to see whether they match.

The defective image according to an embodiment may be an image of the preceding substrate W determined to be defective in the determination step S30 and stored in the database. The initial defective images can be manually selected by the operator and stored in the database. In addition, the initial defective images can be collected by making an image of the substrate W determined to be good quality in the treating step S10 a reference image, by comparing the reference image and the image to be determined, and by selectively storing the image to be determined which does not match the reference image in the database. In addition, if a certain amount of initial defective images are collected, a data on subsequent defective images can be expanded in a deep learning method through an AI.

As described above, if the film formed in the edge region of the substrate W is not well removed at the treating step S10, the boundary line displayed on the substrate W which has been treated is curved. That is, as shown in FIG. 7, the boundary line FL of the defective image FI is not displayed in the form of a portion of a circle with a certain diameter or a part of a curvature circle, but is displayed in a curved manner.

Following the above description, boundary lines displayed on the image to be determined and boundary lines displayed on the plurality of defective images previously stored in the database are compared, respectively.

If the boundary line shown in the image to be determined is inconsistent with all of the boundaries displayed in the plurality of defective images previously stored in the database, the substrate W is determined to be good quality and taken out of the load lock chamber 40 S330. The substrate W which taken out is stored in the container 4.

As described above, there may be a plurality of images to be determined which are acquired from any one substrate W. Accordingly, if all of the plurality of images to be determined on any one substrate W do not match all of the boundaries displayed on the plurality of defective images previously stored in the database, the controller 90 may determine that the treated substrate W is good quality. If the substrate W is determined to be good quality, the substrate W is taken out of the load lock chamber 40. For example, as shown in FIG. 8, the boundary line L (solid line) displayed in the image to be determined I and the boundary line FL (dotted line) displayed in the defective image are inconsistent with each other, so the substrate W can be taken out of the load lock chamber 40. FIG. 8 illustrates an example of comparing a boundary line displayed on one defective image with a boundary line displayed on the plurality of defective images for convenience of understanding, but as described above, each boundary line displayed on the plurality of defective images should be compared with each boundary line displayed on the image to be determined.

Unlike the above, if the boundary line shown in the image to be determined matches at least one boundary line among the boundary lines displayed in the plurality of defective images, the controller 90 determines that the substrate W has been poorly treated in the treating step S10. For example, as described in FIG. 9, the boundary line L (solid line) displayed on the image to be determined I and the boundary line FL (dotted line) displayed on the defective image perfectly match, so the substrate W can be determined as being poorly treated.

In addition, if the boundary line shown in the image to be determined and the boundary line shown in the defective image match in some regions, the controller 90 may determine that the substrate W has been poorly treated in the treating step S10. For example, even if the boundary line L (solid line) shown in the image to be determined I and the boundary line FL (dotted line) shown in the defective image match only in a partial region A, the substrate W may be determined to have been poorly treated.

If it is determined that the boundary line displayed on the image to be determined matches the boundary line displayed on the defective image, the image to be determined is stored in the database S340. Accordingly, the image to be determined stored in the database may function as a defective image. That is, the image to be determined stored in the database may function as any one of the defective images compared to the image to be determined acquired from a subsequent substrate W. Accordingly, it is possible to improve a reliability of the determination by determining whether the substrate W is defective in a treatment and also expanding a data of the database for the defective image.

In addition, when it is determined that the boundary line displayed on the image to be determined matches the boundary line displayed on the defective image, the controller 90 generates a quality alarm S350. If the quality alarm is generated, the operator may discard the corresponding substrate W. Optionally, when the quality alarm is generated, the first transfer robot 25 may selectively transfer the substrate W to any one of a plurality of containers 4 in which the substrate W to be discarded is stored.

In addition, if it is determined that the boundary line shown in the image to be determined matches the boundary line shown in the defective image, a maintenance operation can be performed on the process chamber 60 S360. For example, the maintenance operation may be performed on a component included in the process chamber 60. The component according to an embodiment may be a dielectric plate 640. In addition, the component according to an embodiment may be an insulating ring 623. Hereinafter, for convenience of understanding, a case in which the component is the dielectric plate 640 will be described as an example.

When it is determined that the boundary line displayed on the image to be determined matches the boundary line displayed on the defective image, and the image to be determined is stored in the database, a data on a current state of the dielectric plate 640 matching the image to be determined can be stored in the database.

According to an embodiment, regarding the data on the current state of the dielectric plate 640, the operator may directly measure the current state of the dielectric plate 640 and input the respective data (e.g., grade) into the database. For example, the data may be an expression of a numerical range on whether the current state of the dielectric plate 640 is in good quality as a number is higher, and the current state of the dielectric plate 640 is defective as the number is lower.

However, it is not limited to this, and the data on the current state of the dielectric plate 640 which is determined to be defective and matched with the image to be determined stored in the database can be changed in various ways. For example, the data on the current state of the dielectric plate 640 can be visualized as an image of the dielectric plate 640 currently mounted within the process chamber 60 and shown to the operator.

After the subsequent substrate W is treated in the process chamber 60, it may be transferred to the load lock chamber 40 to perform the determination step S30. If the image to be determined acquired from the subsequent substrate W is determined to match at least one of the defective images stored in the database, the controller 90 can deliver a data (e.g., grade) which matches a subsequent image to the operator. In this case, the operator may determine whether to perform a maintenance operation on the dielectric plate 640 by grasping the current state of the dielectric plate 640 based on a received data. In addition, the operator may determine when to replace the dielectric plate 640 based on the received data.

In addition, the controller 90 may calculate a replacement period of the dielectric plate 640 based on a replacement timing of the dielectric plate 640 according to the received data. According to a calculated replacement period of the dielectric plate 640, a set number of substrates W treated in the process chamber 60 may be calculated. That is, an average number of substrates W that may be treated by the process chamber 60 per cycle may be calculated. After the dielectric plate 640 is replaced, when the substrate W of the set number is treated in the process chamber 60, the controller 90 generates an alarm or an interlock. Accordingly, the operator may immediately replace the dielectric plate 640.

According to the above-described embodiment, when determining whether the treatment of the substrate W is defective, it is possible to easily expand the data of the database for the defective image at the same time. By expanding the data of the database for the defective image, it is possible to further improve a reliability of whether the treated substrate W is defective. In addition, it is possible to determine an appropriate replacement time and replacement cycle for the dielectric plate 640 having a relatively weak plasma resistance. Accordingly, a yield of a substrate W treatment may be further improved.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating method comprising:
treating an edge region of a substrate using a plasma; and
acquiring an image to be determined by imaging a substrate on which a treatment has been completed in the treating the edge region, comparing the image to be determined with an image stored in a database, and determining whether a substrate treated in the treating the edge region is defective or not, and
wherein the image stored in the database is a defective image of a substrate which has been determined as defective, which is previously stored in the database in the acquiring the image to be determined.

2. The substrate treating method of claim 1, wherein in the acquiring the image to be determined, if the image to be determined matches any one among defective images, it is determined that a treatment is defective in the treating the edge region.

3. The substrate treating method of claim 2, wherein if the image to be determined matches any one among the defective images, the image to be determined is stored in the database.

4. The substrate treating method of claim 1, wherein if the image to be determined matches any one among the defective images, a maintenance operation with respect to a component of a process chamber performing the treating the edge region is performed.

5. The substrate treating method of claim 4, wherein the process chamber includes:
a support unit configured to support the substrate;
a dielectric plate positioned above the support unit to face a central region of a substrate supported on the support unit; and
a plasma source generating a plasma at an edge region of the substrate supported on the support unit, and
wherein the component includes a dielectric plate.

6. The substrate treating method of claim 5, wherein when the image to be determined matches any one among the defective images, when the image to be determined is stored in the database, a data of a current state of the dielectric plate matching the image to be determined is stored in the database, and
if it is determined that a subsequent image to be determined matches at least any one among the defective images, a replacement time of the dielectric plate is determined based on the data which is matched with the subsequent image to be determined.

7. The substrate treating method of claim 6, wherein a replacement period of the dielectric plate is calculated based on a determined replacement time, and
a set number of the substrate treated in the treating the edge region is calculated according to the replacement period, and if a substrate of a calculated set number is treated at the treating the edge region, the dielectric plate is replaced.

8. The substrate treating method of claim 1, wherein at the acquiring the image to be determined, whether a boundary displayed on the image to be determined and a boundary displayed on the defective image is determined, and
the boundary is between the edge region of the substrate which is treated by the plasma and a central region of the substrate.

9. The substrate treating method of claim 1 wherein the substrate having the edge region treated is transferred to a load lock chamber in the treating the edge region, and the acquiring the image to be determined is performed in the load lock chamber.

10. The substrate treating method of claim 9, wherein in the load lock chamber the image to be determined is acquired by imaging the edge region of the chamber by rotating the substrate.

11. A substrate treating method comprising:
treating an edge region of a substrate using a plasma at a process chamber including a plasma source generating the plasma at the edge region of the substrate supported on a support unit and a dielectric plate positioned above the support unit to face the support unit;
acquiring an image to be determined by imaging a substrate on which a treatment is completed, and determining whether the image to be determined and an image stored in a database match; and
performing a maintenance operation on the dielectric plate if the image to be determined matches at least any one among images stored in the database.

12. The substrate treating method of claim 11, wherein the image stored in the database is a defective image of a substrate which has been determined as needing the maintenance operation, which is previously stored in the database.

13. The substrate treating method of claim 12, wherein when the image to be determined matches any one among defective images and the image to be determined is stored in the database, a data of a current state of the dielectric plate matching the image to be determined is stored in the database, and
if it is determined that a subsequent image to be determined matches at least any one among the defective images, a replacement time of the dielectric plate is determined based on the data which is matched with the subsequent image to be determined.

14. The substrate treating method of claim 13, wherein a replacement period of the dielectric plate is calculated based on a determined replacement period.

15. The substrate treating method of claim 14, wherein a set number of a substrate treated using the plasma is calculated according to the replacement period, and if a substrate of a calculated set number is treated, the dielectric plate is replaced.

16. The substrate treating method of claim 12, wherein whether the image to be determined matches the defective image is determined based on whether a boundary displaying the image to be determined and a boundary displayed on the defective image match, and
the boundary is between the edge region of the substrate which is treated by the plasma the central region of the substrate.
